(19) United States
(12) Patent Application Publication
(10) Pub. No.: US 2025/0133866 A1
(43) Pub. Date: Apr. 24, 2025

(54) III-NITRIDE-BASED HIGH EFFICIENCY AND HIGH-POWER DEVICES GROWN ON OR ABOVE A STRAIN RELAXED TEMPLATE

(71) Applicant: The Regents of the University of California, Oakland, CA (US)

(72) Inventors: Philip Chan, Goleta, CA (US); Hsun-Ming Chang, Goleta, CA (US); Vincent Rienzi, Goleta, CA (US); Shuji Nakamura, Santa Barbara, CA (US)

(73) Assignee: The Regents of the University of California, Oakland, CA (US)

(21) Appl. No.: 18/730,604

(22) PCT Filed: Feb. 1, 2023
(86) PCT No.: PCT/US23/61748

§ 371 Date: Jul. 19, 2024

Related U.S. Application Data
(60) Provisional application No. 63/305,441, filed on Feb. 1, 2022.

(51) Int. Cl. H10H 20/01; H01S 5/20; H01S 5/34; H01S 5/343; H10H 20/815; H10H 20/825

(52) U.S. Cl. CPC H10H 20/01335; H01S 5/2009; H01S 5/2018; H01S 5/3425; H01S 5/34333; H10H 20/815; H10H 20/825

(57) ABSTRACT

A method of growing III-nitride-based devices, such as light emitting diodes (LEDs) and laser diodes (LDs) on or above a strain relaxed template (SRT). The SRT uses a thin, thermally decomposed, InGaN underlayer, which is referred to as a decomposition layer (DL). Above the DL is a n-type GaN or low composition InGaN decomposition stop layer (DSL). A buffer layer comprising an n-type InGaN/GaN superlattice (SL) is then grown. For an LD structure. an n-type waveguide layer comprising a second n-type InGaN/GaN SL is then grown. followed by an active region, a p-type electron blocking layer (EBL), a p-type waveguide layer comprising a p-type InGaN/GaN SL, and p-type GaN or p-type InGaN layers. For an LED structure, the waveguide layers may be omitted. In this disclosure, AlGaN means AlₓGa₍₁₋ₓ₎N with 1≥x≥0 and InGaN means InₓGa₍₁₋ₓ₎N with 1≥x≥0.

### CROSS REFERENCE TO RELATED APPLICATIONS

This application claims the benefit under 35 U.S.C. Section 119 (e) of the following co-pending and commonly-assigned application:
U.S. Provisional Application Ser. No. 63/305,441, filed on Feb. 1, 2022, by Philip Chan, Hsun-Ming Chang, Vincent Rienzi and Shuji Nakamura, entitled “III-NITRIDE-BASED HIGH EFFICIENCY AND HIGH-POWER DEVICES GROWN ON OR ABOVE A STRAIN RELAXED TEMPLATE,” attorneys' docket number G&C 30794.0813USP1 (UC 2022-775-1);
which application is incorporated by reference herein.

This application is related to the following co-pending and commonly-assigned applications:
PCT International Patent Application Serial No. PCT/US22/28264, filed on May 9, 2022, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802WOUI (UC 2021-888-3), which application claims the benefit under 35 U.S.C. Section 119 (e) of the following co-pending and commonly-assigned applications:
U.S. Provisional Application Ser. No. 63/186,749, filed on May 10, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP1 (UC 2021-888-1); and
U.S. Provisional Application Ser. No. 63/230,205, filed on Aug. 6, 2021, by Philip Chan, Steven P. DenBaars and Shuji Nakamura, entitled “III-NITRIDE BASED DEVICES GROWN ON A THIN TEMPLATE ON THERMALLY DECOMPOSED MATERIAL,” attorneys' docket number G&C 30794.0802USP2 (UC 2021-888-2); and
PCT International Patent Application Serial No. PCT/US22/42526, filed on Sep. 2, 2022, by Norleakvisoth Lim, Philip Chan, Steven P. Denbaars, Michael J. Gordon and Shuji Nakamura, entitled “III-NITRIDE-BASED DEVICES GROWN ON OR ABOVE A STRAIN COMPLIANT TEMPLATE,” attorneys' docket number G&C 30794.0806WOUI (UC 2022-760-2), which application claims the benefit under 35 U.S.C. Section 119(e) of the following co-pending and commonly-assigned applications:
U.S. Provisional Application Ser. No. 63/240,517, filed on Sep. 3, 2021, by Norleakvisoth Lim, Philip Chan, Steven P. Denbaars, Michael J. Gordon and Shuji Nakamura, entitled “III-NITRIDE BASED DEVICES GROWN WITH A RELAXED ACTIVE REGION,” attorneys' docket number G&C 30794.0806USP1 (UC 2022-760-1); and
U.S. Provisional Application Ser. No. 63/245,105, filed on Sep. 16, 2021, by Philip Chan, Steven P. DenBaars and Shuji Nakamura, entitled “SURFACE MORPHOLOGY OF III-NITRIDE-BASED DEVICES GROWN ON OR ABOVE A STRAIN COMPLIANT TEMPLATE,” attorneys' docket number G&C 30794.0808USP1 (UC 2022-763-1);
all of which applications are incorporated by reference herein.

### STATEMENT REGARDING FEDERALLY SPONSORED RESEARCH AND DEVELOPMENT

This invention was made with Government support under Grant No. HR001120C0135 awarded by the Defense Advanced Research Projects Agency (DARPA). The Government has certain rights in this invention.

### BACKGROUND OF THE INVENTION

### 1. Field of the Invention

This invention relates to improvement of III-nitride-based light-emitting diodes (LEDs) and laser diodes (LDs) grown on or above a strain relaxed template (SRT).

### 2. Description of Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

III-nitride-based blue, green and red LDs have applications in laser lighting and projectors. [1,2] However, in the III-nitrides, green LDs lag blue LDs significantly in output power and efficiency, while edge-emitting LDs grown by metalorganic chemical vapor deposition (MOCVD) emitting at wavelengths longer than green have yet to be realized. In a comparison report by Murayama et al., state-of-the-art watt-class green and blue LDs were grown on semipolar (20-21) and c-plane, respectively. [3] The reported indium-gallium-nitride (InGaN) based 530 nm

LD with record efficiency showed a continuous wave (CW) output of 2 Watts (W) and 17.5% wall-plug efficiency (WPE). However, in the same report, the c-plane blue laser achieved 5.2 W CW output and 37% wall-plug efficiency.

Long wavelength InGaN emitters are challenging and less efficient due to the more than 10% lattice mismatch between indium nitride (InN) and gallium nitride (GaN). The large lattice mismatch causes high strain in the active region which causes defects, a degradation of surface morphology, and reduces indium incorporation in an effect called compositional pulling. [4,5]

By growing the InGaN active region on a strain relaxed InGaN buffer layer, the lattice mismatch between the two layers is reduced. This reduces the compositional pulling effect and allows for higher indium incorporation by hotter growth using MOCVD, the dominant method of commercial epitaxial InGaN growth. Hotter growth temperatures tend to lead to higher crystal quality.

There are several methods of creating strain relaxed InGaN buffer layers by MOCVD. Two of the more recent and well-studied approaches use nano-porous GaN [6-9] or SOITECH's Smart Cut™ technology. [5,10,11] Both methods can produce relaxed InGaN pseudo substrates but require complex processing and patterning of the planar surface into tiles. In the case of nano-porous InGaN pseudo substrates, these tiles need to be on the order of 10 μm×10 μm. In the case of the SOITECH's InGaNOS substrates, the tile size is hundreds of μms to a side. In both cases, the tile size is too small to create an efficient LD which is typically over 1 mm long.

Another technique is using a strain relaxed template (SRT) comprised of a decomposition stop layer (DSL) on top of a thermally decomposed underlayer, which is referred to as a decomposition layer (DL). [12,13] By thermally decomposing the buried DL, voids are formed and an increase in the in-plane lattice constant is observed. This technique has been previously reported to relax an In_{0.04}Ga_{0.96}N layer by 85%. [12] In another report, red LEDs were demonstrated with a record high active region growth temperature of 870° C. on a fully relaxed In_{0.07}Ga_{0.93}N buffer using this technique. [13]

In our previous inventions using this technique to produce the SRT, the primary focus was creating LEDs emitting in the red wavelengths. As such, the DL and DSL were optimized for large expansions of the in-plane lattice constant with relaxed, high indium composition, buffer layers. With improvement in the DSL, buffer, waveguide, active region and p-type cladding layers, this technique is able to achieve high efficiency and high power emission from a device structure with waveguides in the green wavelengths on a partially relaxed InGaN buffer layer.

### SUMMARY OF THE INVENTION

The present invention discloses a method of growing III-nitride-based devices, such as LEDs and LDs, on or above an SRT. The SRT uses a thin, thermally decomposed InGaN underlayer, the DL. Above the DL is a n-type GaN or low indium composition InGaN DSL. A buffer layer comprising an n-type InGaN/GaN superlattice (SL) is then grown above the DSL. For an LD structure, an n-type InGaN waveguiding layer is then grown, followed by an active region, p-type electron blocking layer (EBL), p-type InGaN waveguide and p-type GaN or p-type InGaN layers. For an LED structure, the n-type, p-type or both InGaN waveguiding layers may be omitted. In this disclosure, AlGaN means AlₓGa₍₁₋ₓ₎N with 1≥x≥0, and InGaN means InₓGa₍₁₋ₓ₎N with 1≥x≥0.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 illustrates an embodiment of the present invention comprising an epitaxial structure of an LD or LED on a SRT.

FIG. 2 illustrates an embodiment of the present invention comprising an epitaxial structure of an active region, wherein one period of a multi-quantum well (MQW) is shown to contain an InGaN quantum well (QW) grown at temperature T₁, an AlGaN cap layer grown at temperature T₁ and a GaN barrier grown at temperature T₂ where T₂>T₁.

FIGS. 3(a), 3(b), 3(c) and 3(d) are atomic force micrograph (AFM) images of cracking seen in an SRT and buffer layer with a 3 μm thick DSL, wherein the maximum DSL thickness is dependent on various parameters of the DL growth but must remain below the critical thickness to prevent cracking under tensile stress.

FIGS. 4(a) and 4(b) are graphs of power (mW) vs. current (mA) and voltage (V) vs. current (mA) with light-current-voltage curves of devices showing the improvements of the structure by including hot barriers in a partial hydrogen ambient as used in the present invention, wherein the light-current-voltage curves in FIG. 4(a) comprise a previous structure and in FIG. 4(b) comprise the present invention with a slightly altered buffer layer improved by the incorporation of hot barriers in a partial hydrogen ambient.

FIG. 5(a) is a 5 μm×5 μm AFM image and FIG. 5(b) is a high resolution x-ray diffraction reciprocal space map (RSM) around the (−1-124) peak of the present invention, wherein the AFM image in FIG. 5(a) shows a step-flow morphology with pitting, and the RSM in FIG. 5(b) shows the buffer layer to be an average composition of In_{0.025}Ga_{0.975}N that is 53% relaxed and the n-type waveguide layer to be an average composition of In_{0.125}Ga_{0.875}N that is 21% relaxed.

FIG. 6(a) is a graph of power (mW) vs. current (mA) and voltage (V) vs. current (mA) with light-current-voltage curves of the present invention and FIG. 6(b) is a graph of intensity (A.U.) vs. wavelength (nm) with light output curves of the present invention, with GaN and AlGaN cap layers in the active region, wherein FIG. 6(a) shows the improvement of the light-current-voltage characteristics of the device with the inclusion of AlGaN cap layers in the active region, and FIG. 6(b) shows the narrowed spectrum after inclusion of AlGaN cap layers in the active region.

FIG. 7 is a graph of power (mW) vs. current (mA) and voltage (V) vs. current (mA) with light-current-voltage curves of three devices with varying p-GaN cladding thicknesses, wherein a 150 nm p-GaN cladding shows improved performance over 100 nm and 50 nm p-GaN cladding.

FIG. 8 is a flowchart that illustrates the steps for a process of fabricating a III-nitride-based device, according to the present invention.

### DETAILED DESCRIPTION OF THE INVENTION

In the following description of the preferred embodiment, reference is made to the accompanying drawing which forms a part hereof, and in which is shown by way of illustration a specific embodiment in which the invention may be practiced. It is to be understood that other embodiments may be utilized, and structural changes may be made without departing from the scope of the present invention.

### Technical Description

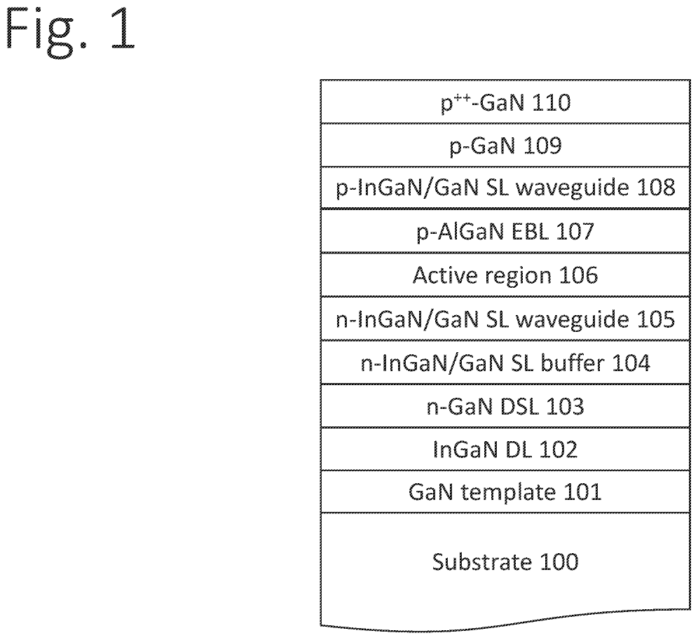

FIG. 1 shows the epitaxial structure of the full device in the preferred embodiment. The substrate 100 used for growth may be sapphire (patterned or polished), silicon or bulk GaN with a normal face of any crystal plane. All results presented herein are on patterned sapphire substrates 100.

On top of the substrate 100 is an n-type or unintentionally doped (UID) GaN template 101 with a typical thickness between 2 and 10 μm. The purpose of this layer 101 is to nucleate good crystal growth for subsequent layers, and conditions are dependent on the choice of substrate 101.

The SRT comprised of an InGaN DL 102 and n-GaN DSL 103 is then grown. These layers 102, 103 have been discussed in depth in the prior art and the related applications set forth above. The DL 102 is grown as either a single high indium composition InGaN layer, or a series of InGaN layers with GaN, lower composition InGaN or AlGaN interlayers between the InGaN layers. These layers of the DL 102 are typically grown between 700° C. and 780° C. to achieve a high indium composition. In the preferred embodiment, and for all results shown herein, the DL 102 is a single, high indium composition InGaN layer. The DL 102, as a single layer or a series of layers, serves to thermally decompose and allow for an expansion of the in-plane lattice constant.

The n-GaN DSL 103 is then grown. Alternatively, the DSL 103 may comprise UID GaN. First, a cap layer of GaN, AlGaN, or lower indium composition InGaN, is grown at or near the growth temperature of the DL 102, which serves to preserve the DL 102. Then, GaN is grown at a high temperature over 1000° C. to recover morphologically smooth, step-flow growth and decompose the DL 102 to cause relaxation. This high temperature GaN growth is done at first in a nitrogen carrier gas to prevent gas-etching of the indium-containing SRT before switching to hydrogen or a mixture of hydrogen and nitrogen carrier gases to further improve the morphology. The DSL 103 is grown more than 300 nm thick to provide good morphology and less than 2 μm thick to prevent cracking due to tensile stress. In the case of an LD structure, the thickness of n-GaN DSL 103 should be more than 300 nm to work as a cladding layer to confine the lasing mode and prevent loss from the decomposed InGaN DL 102.

Next, a buffer layer 104 formed by a first n-type InGaN/GaN superlattice (SL) is grown in a nitrogen carrier gas on the DSL 103. The layers of the n-type InGaN/GaN SL that is the buffer layer 104 are grown at temperatures above 900° C. to maintain good morphology. The buffer layer 104 is between 100 and 1000 nm thick. The average indium composition of the buffer layer 104 should be low, typically between 1% and 5% to allow for adequate confinement in a LD structure.

A second n-type InGaN/GaN SL is then grown on the buffer layer 104 to act as an n-type waveguide layer 105 in the LD structure. The average indium composition of this n-type waveguide layer 105 should be between 5% and 20% depending on the exact specifications of other layers to obtain adequate waveguiding and confinement of the laser mode. The n-type waveguide layer 105 comprises n-type InGaN layers grown at a temperature under 900° C. in a nitrogen carrier gas to achieve a high indium composition. The n-type InGaN layers are then capped with GaN in a nitrogen carrier gas and then the rest of the GaN layers are grown at a higher temperature, similar to that of p-type GaN, namely, over 900° C., in a partial hydrogen carrier gas to achieve good morphology. The n-type waveguide layer 105 should be thick enough to achieve adequate mode confinement for lasing but thin enough to prevent relaxation further than that provided by the SRT. The typical thickness of the n-type waveguide layer 105 is 40 nm to 100 nm with the indium composition of between 8% and 13%.

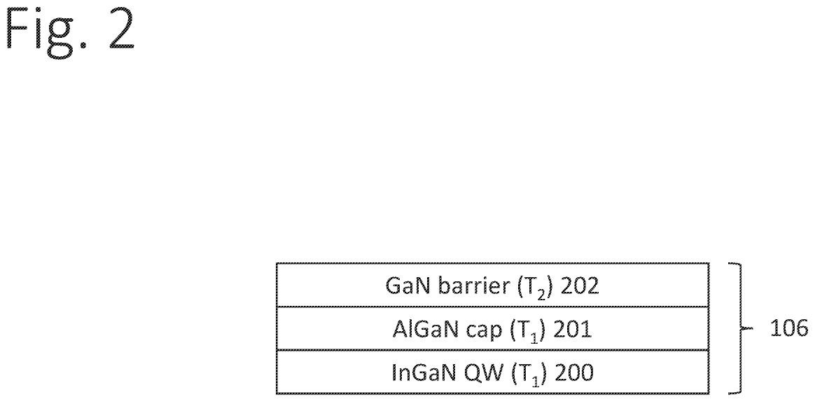

An active region 106 structure is grown on the waveguide 105. One period of the active region 106 structure is shown in FIG. 2. The active region 106 is comprised of one or more periods of InGaN quantum wells (QWs) 200 grown in a nitrogen carrier gas at temperature T₁, AlGaN cap layers 201 grown in a nitrogen carrier gas at temperature T₁, and GaN barriers 202 grown at a higher temperature T₂, similar to that of p-type GaN, namely, over 900° C., in a partial hydrogen carrier gas to achieve good morphology and/or a high output power of LED and LD.

Referring again to FIG. 1, a p-type AlGaN EBL 107 may be included to prevent electron overflow from the active region 106. This layer 107 should be highly doped p-type and between 15% and 40% Al.

A p-type waveguide layer 108 comprising a p-type InGaN/GaN SL is then grown using a similar layer structure to that of the n-type InGaN/GaN SL that is the n-type waveguide layer 105, with GaN interlayers grown at a high temperature, similar to that of p-type GaN, namely, over 900° C., in a partial hydrogen to recover morphology.

A p-type GaN cladding 109 not less than 100 nm thick is grown at a temperature over 900° C. in a hydrogen carrier gas. The thickness of the p-type GaN cladding 109 greatly affects the loss and confinement in the LD structure due to mode overlap with a p-contact transparent conducting oxide or metal.

Finally, a p⁺⁺-GaN contact layer 110 is grown in a hydrogen carrier gas to allow for electrical contact to the device. Additionally, an n⁺⁺-GaN or n⁺⁺-InGaN layer (not shown) may be used to form a tunnel junction contact to the device but are not necessary.

In one embodiment of the present invention, an LD or LED structure is grown on a patterned sapphire substrate (PSS) 100 with a 7 μm n-GaN template 101. The SRT is comprised of the DL 102 that is a 3 nm InGaN layer grown in an N₂ carrier gas at 750° C. capped with the DSL 103 that is a 2 nm UID-GaN at 750° C., 2 nm GaN at 875° C. and 2 nm UID-GaN at 1000° C. with a 1 μm n-GaN grown in H₂ carrier gas at 1100° C. The buffer layer 104 contains 25 periods of 5 nm InGaN in an N₂ carrier gas and 5 nm GaN in an N₂ carrier gas at an average composition of In_{0.025}Ga_{0.975}N grown at 930° C. The n-type waveguide layer 105 contains 3 periods of 16 nm InGaN in an N₂ carrier gas and 4 nm GaN with an average In_{0.125}Ga_{0.875}N composition with the InGaN layer grown at 880° C., capped with 2 nm GaN at 880° C. in 100% N₂ carrier gas and then 2 nm GaN at 920° C. in 5% H₂ and 95% N₂ carrier gas. The 4× MQW active region 106 has 2.5 nm InGaN QWs 200 grown in an N₂ carrier gas at 830° C., 2 nm AlGaN cap layers 201 (nominally 40% Al) grown in an N₂ carrier gas at 830° C., and 9 nm GaN barriers 202 grown at 920° C. in a 5% H₂ and 95% N₂ carrier gas. A 10 nm p-AlGaN EBL 107 in an N₂ carrier gas is followed by a p-type waveguide layer 108 of identical SL structure to the n-type waveguide 105. Finally, a 150 nm p-GaN cladding 109 and a 15 nm p⁺⁺-GaN contact layer 110 are grown at 920° C. in a 100% H₂ ambient.

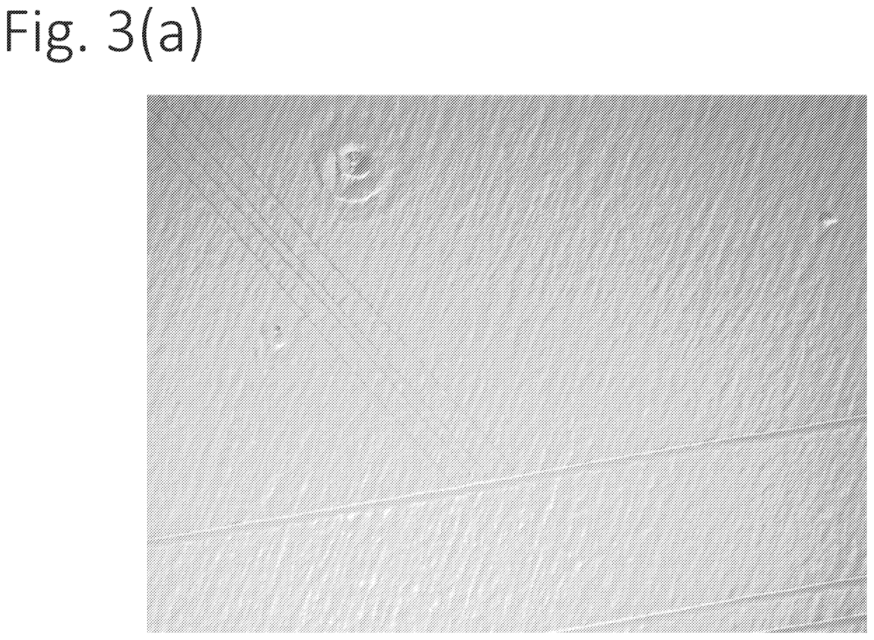

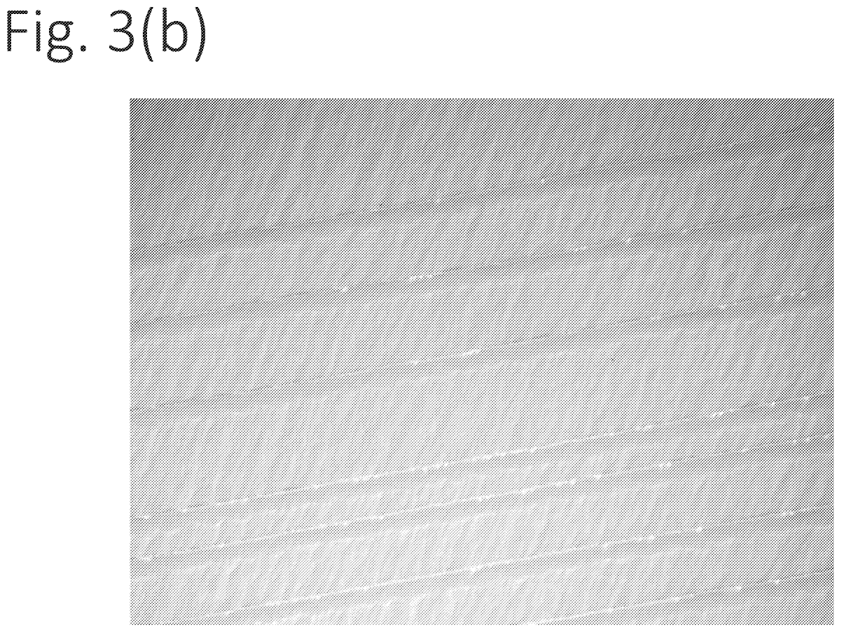

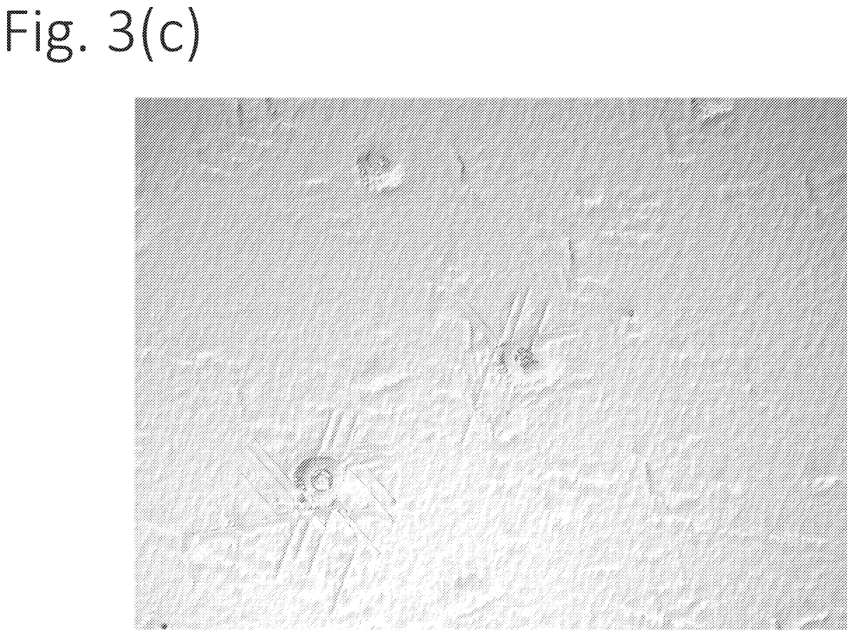

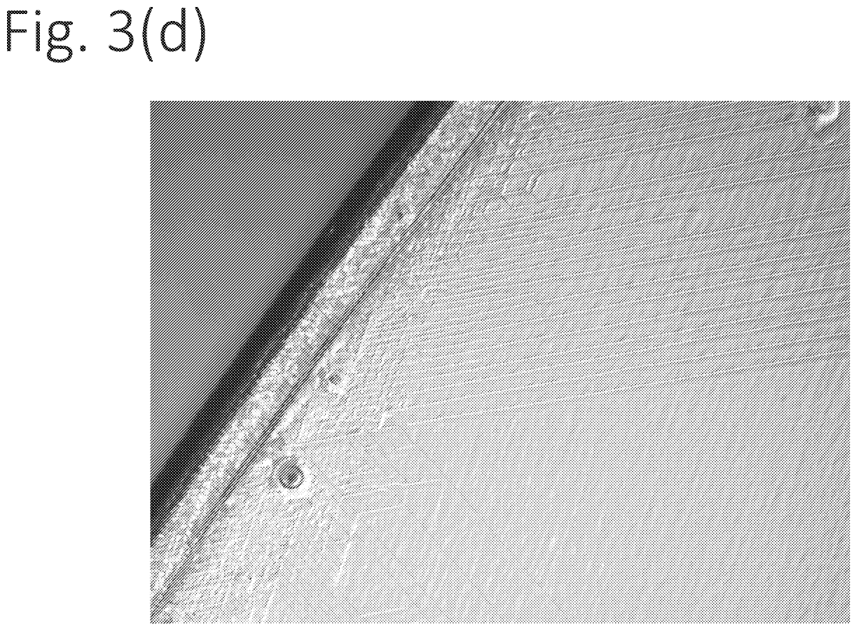

The DSL 103 thickness in the present invention was optimized to be 1 μm of n-GaN. However, the optimal thickness is dependent upon the growth conditions of the DL 102 in the SRT. Thicker DSLs 103 yield better morphology due to the high temperature growth of GaN in H₂ as well as the potential for better LD characteristics from lower modal overlap with the lossy, decomposed DL 102. However, the DSL 103 is in tensile strain and must be grown below the critical thickness to prevent cracking. FIGS. 3(a), 3(b), 3(c) and 3(d) show the result of a DSL with the thickness of 3 microns grown too thick, resulting in cracking of the film. A 1 μm thick n-GaN DSL results in no cracking in with the given SRT parameters in the present invention.

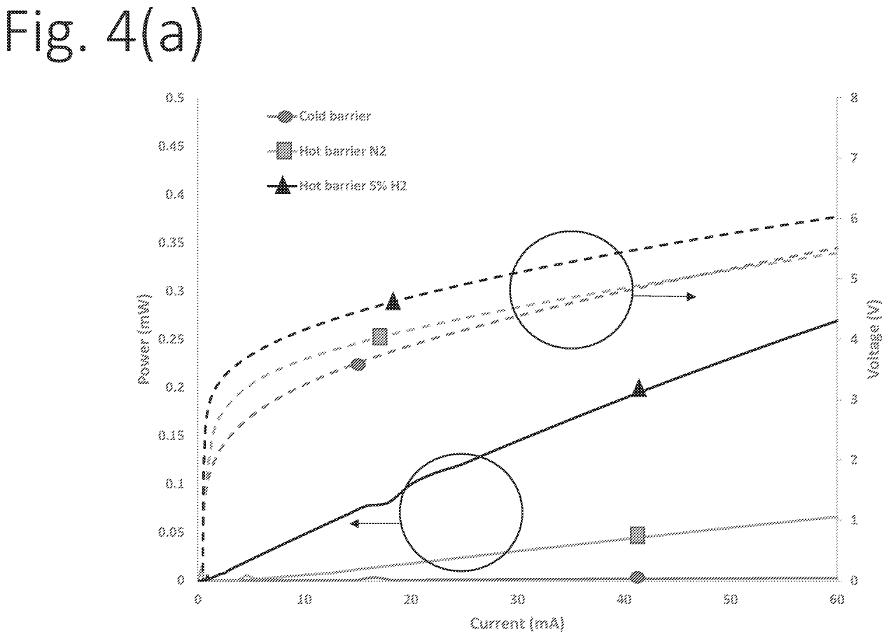

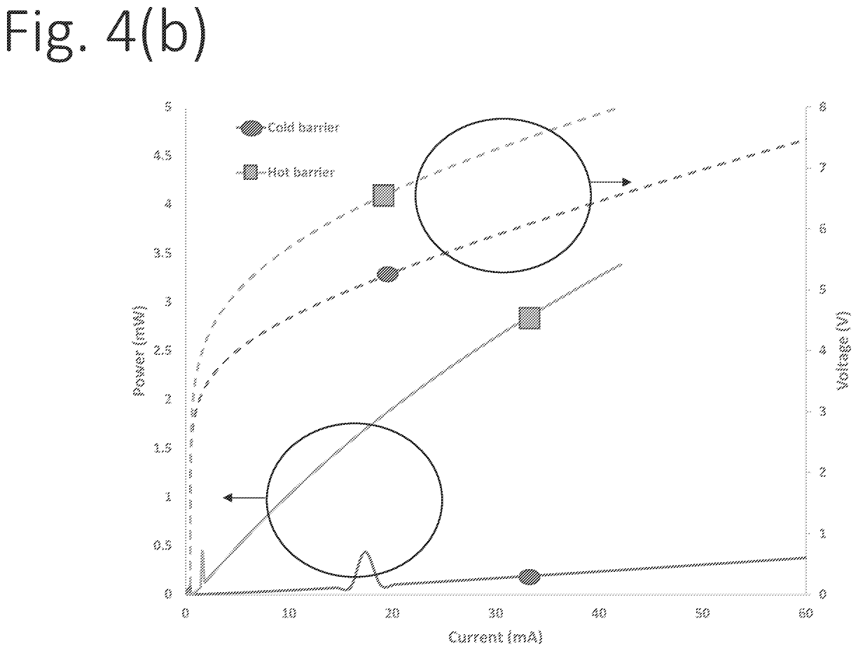

FIGS. 4(a) and 4(b) show device improvement by growing the barrier of the active region 106 at a higher temperature than the quantum well in a partial hydrogen ambient. The structures used for FIG. 4(a) include the SRT 102, 103 and buffer layer 104 from the present invention, but omit the n-type and p-type waveguide layers 105, 108. The active regions 106 for the devices presented in FIG. 4(a) are comprised of 4 periods of 2.5 nm InGaN QWs grown in an N₂ carrier gas at 770° C., 2 nm GaN cap layers grown in an N₂ carrier gas at 770° C., and 9 nm GaN barriers grown at 770° C. in N₂, 920° C. in N₂ and 920° C. in 5% H₂ and 95% N₂. The p-GaN layers were grown to 45 nm in an H₂ carrier gas, with the last 15 nm of which doped higher as p⁺⁺-GaN in an H₂ carrier gas. As shown, significant improvements were seen in the light-current curves moving from a cold barrier grown at the QW growth temperature to a hot barrier and then adding hydrogen to the carrier gas during barrier growth.

This is shown further in FIG. 4(b). The epitaxial layer structures are the same as the present invention with a slightly altered buffer layer 104 and active region 106. The buffer layer 104 contained only 20 periods of an InGaN/GaN SL. The active region 106 was 4 periods of 2.5 nm InGaN QWs grown at 830° C., 2 nm GaN cap layers grown in an N₂ carrier gas at 830° C. and 9 nm GaN barriers grown at either 830° C. in N₂ or 920° C. in 5% H₂ and 95% N₂. Again, significant improvement in the light-current curves is demonstrated by growing the barrier at the p-GaN growth temperature (920° C.) in a partial hydrogen ambient.

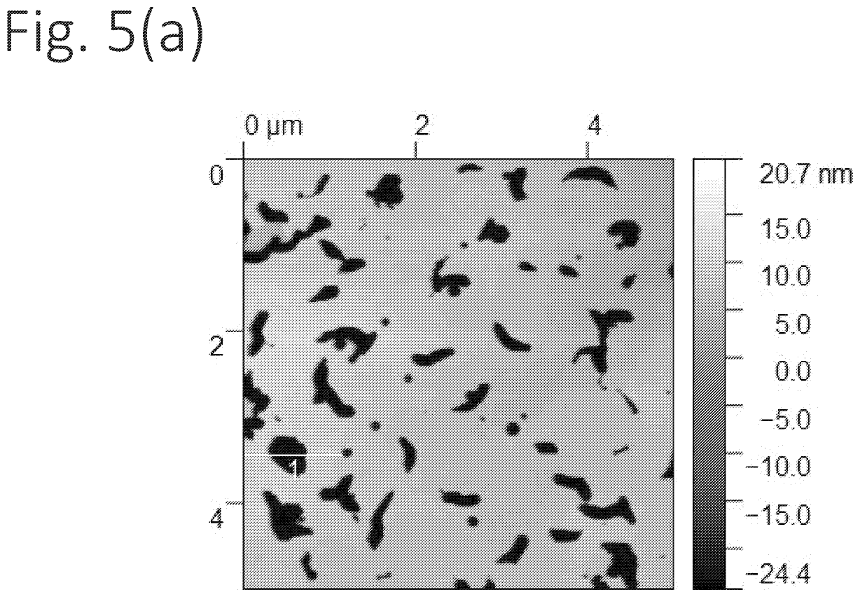

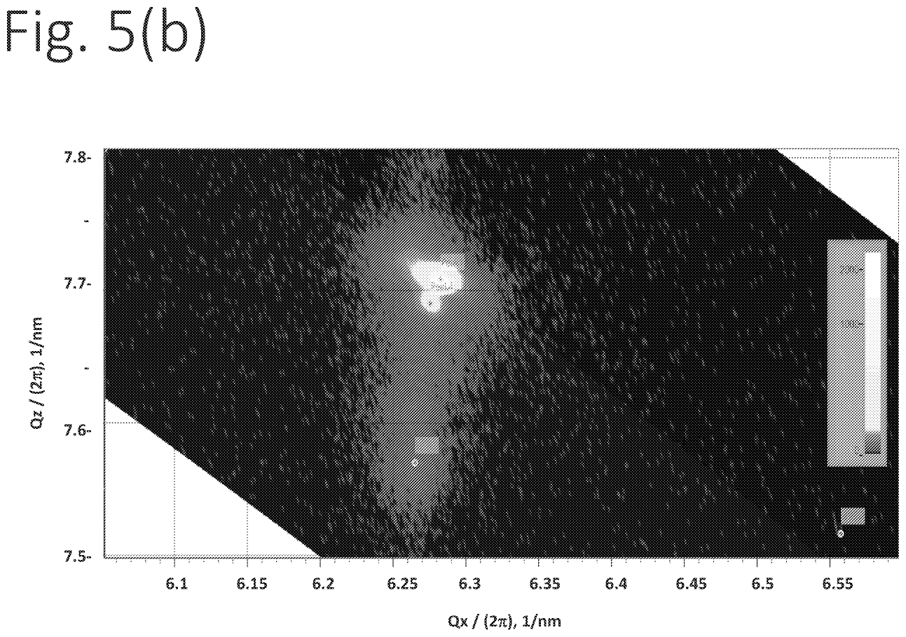

The morphology of the present invention of LD or LED structures with hot barriers in partial hydrogen ambient is shown in FIG. 5(a). Some pitting is seen on a surface that is otherwise in a step-flow growth mode. A high-resolution x-ray diffraction reciprocal space map taken about the off-axis (−1-124) peak is shown in FIG. 5(b). The off-axis reciprocal space map allows determination of the InGaN buffer layer 104 and waveguide layer 105 composition and strain state. The InGaN buffer layer 104 is shown to be an average composition of In_{0.025}Ga_{0.975}N that is 53% relaxed and the n-type waveguide layer 105 is shown to be an average composition of In_{0.125}Ga_{0.875}N that is 21% relaxed.

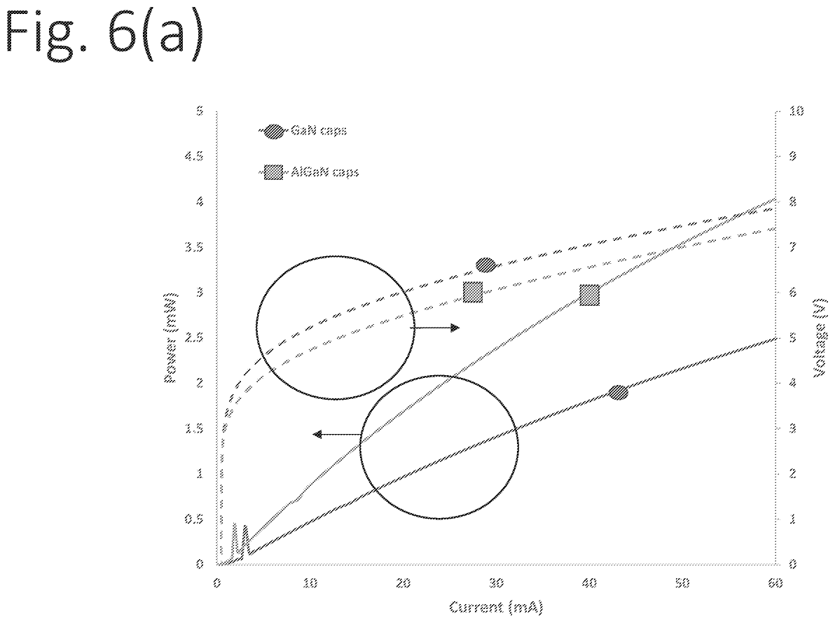

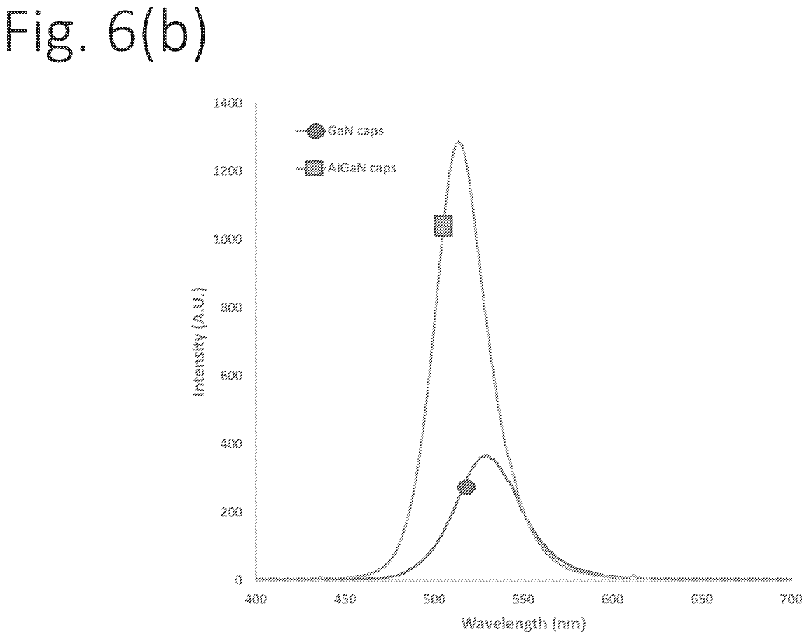

FIGS. 6(a) and 6(b) show the benefit of replacing the 2 nm GaN cap layer in the active region 106 with AlGaN (nominally 40% Al). The structure is identical to the present invention. FIG. 6(a) shows the light output power-current-voltage curves for the two devices while FIG. 6(b) shows the spectrum at 20 mA. The improvement in the light output power-current curve is apparent from the higher output power at a given current. The spectrum with the AlGaN cap layers also has improved from a full-width half maximum of 44 nm with the GaN cap layer to 35 nm with the AlGaN cap layer.

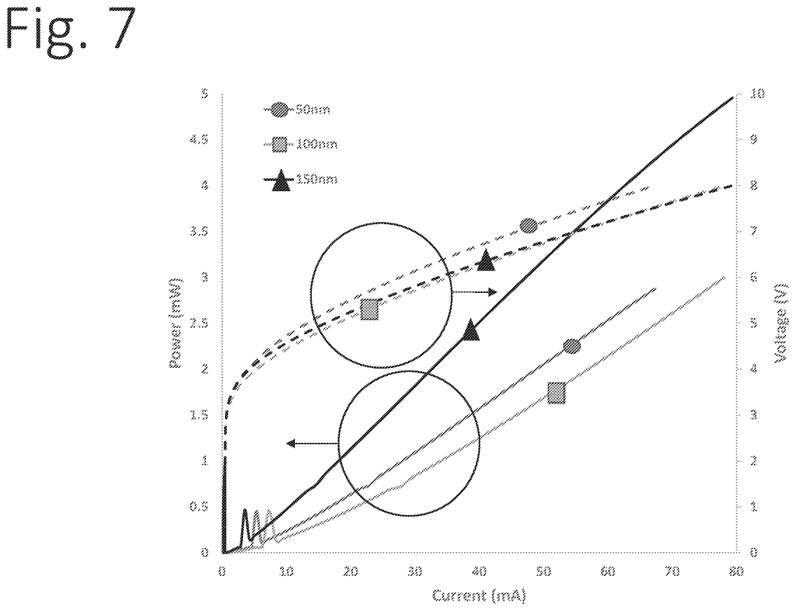

The thickness of the p-type GaN layer 109 is important in an LD to control the confinement and loss in the lasing mode due to overlap with the highly doped p-type contact layer 110 and a metal or transparent conducting oxide p-contact (not shown). The thickness of the p-type layer 109 also affects the quality of the active region 106. FIG. 7 shows a series of devices with varying p-GaN 109 thicknesses. The structures had the same SRT 102, 103 as presented before with 20 periods of 5 nm n-InGaN and 5 nm n-GaN grown at 930° C. corresponding to an average SL indium composition of about 2.5%. The active region 106 is comprised of 4 periods of 2.5 nm InGaN QWs grown at 830° C. and 11 nm GaN barriers grown at 830° C. in N₂ followed by a 10 nm p-AlGaN EBL. The p-GaN 109 was 50 nm, 100 nm or 150 nm thick, and had an additional 15 nm which was doped higher as p⁺⁺-GaN 110. The light-current curves are presented in FIG. 6(a) showing a significant improvement at with 150 nm of p-GaN 109.

Precursors used during growth of all layers include triethylgallium (TEG), trimethylgallium (TMG), trimethylindium (TMI), trimethylaluminum (TMA), disilane, biscyclopentadienylmagnesium (Cp2Mg), and ammonia (NH₃) though other precursors may be used. The light output power-current-voltage data presented was taken on planar epilayers with soldered indium n-contacts and 0.1 mm² indium p-contacts with a photodetector located below the substrate. This technique is referred to as “quick-test” (QT).

As referred to herein, III-nitride-based materials include InN, GaN, AlN, ScN, InGaN, AlScN, AlGaN, InAlN, InScN, InGaAlN, InGaAlScN and other nitride-based materials.

### Process Flowchart

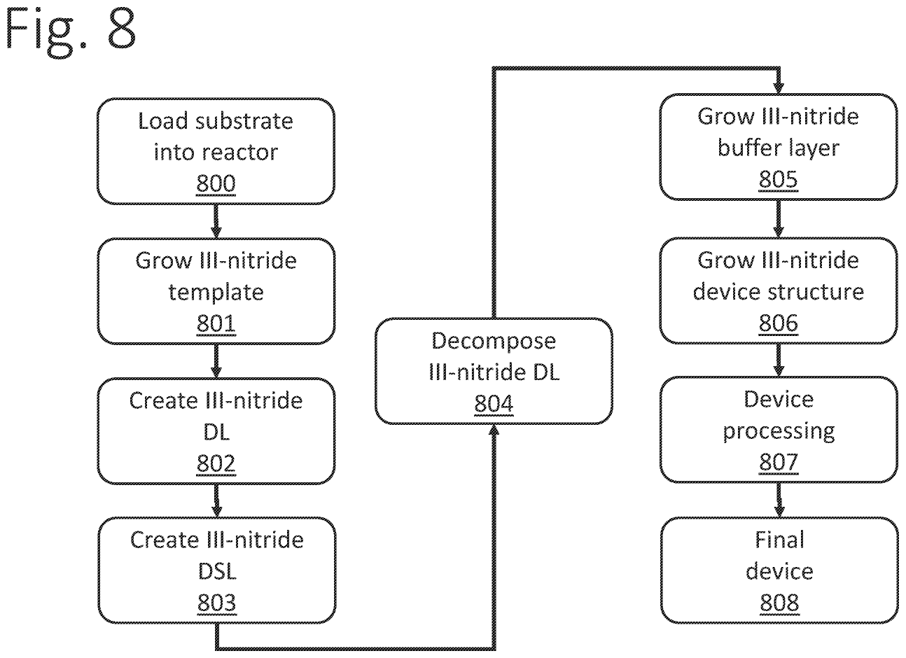

FIG. 8 is a flowchart that illustrates the steps for a process of fabricating a III-nitride-based device, according to the present invention. Specifically, the flowchart illustrates the steps for a method comprising fabricating a III-nitride-based device using a strain relaxed template (SRT) that allows subsequent layers to relax so that the subsequent layers are not coherently strained to a substrate or a template layer on the substrate.

Block 800 represents the step of loading a substrate into a chamber of an MOCVD reactor. The substrate may comprise sapphire, silicon (Si), silicon carbide (SiC), glass, III-nitride-based materials such as GaN and AlN with any crystal orientation such as nonpolar and semipolar, or other materials.

Block 801 represents the optional step of growing a III-nitride-based template on or above the substrate. The III-nitride-based template may comprise GaN when fabricating InGaN-based devices.

Blocks 802-803 represent the steps of creating the strain relaxed template, wherein the strain relaxed template is comprised of a decomposition layer and a decomposition stop layer.

Block 802 represents the step of creating a III-nitride-based decomposition layer (DL) on or above the III-nitride-based template and/or the substrate.

In one embodiment, the DL is comprised of InGaN or multiple periods of an InGaN/GaN superlattice (SL) grown at a temperature between 700° C. and 800° C. Block 803 represents the step of creating a III-nitride-based decomposition stop layer (DSL) on or above the III-nitride-based decomposition layer.

In alternative embodiments, the DSL may comprise n-type GaN or an n-type InₓGa₁₋ₓN/GaN SL with x<0.05.

For example, the DSL may comprise n-type GaN with a thickness greater than 20 nm and with a thickness less than 3 μm. The DSL may comprise n-type GaN grown at a temperature higher than 1000° C. with the inclusion of hydrogen in the carrier gas. A first layer of the n-type GaN may be grown using a carrier gas consisting essentially of nitrogen.

Block 804 represents the step of decomposing the III-nitride-based decomposition layer, but not decomposing the III-nitride-based decomposition stop layer, by an increase in temperature.

This step may be performed as part of Block 803 when epitaxially growing the III-nitride-based decomposition stop layer. Alternatively, the structure may be annealed at a high temperature in Block 804 to decompose or melt the III-nitride-based decomposition layer, which has a lower sublimation temperature or melting point than the III-nitride-based decomposition stop layer.

Block 805 represents the step of epitaxially growing a III-nitride-based buffer layer on or above the III-nitride-based decomposition stop layer after the III-nitride-based decomposition layer is decomposed, wherein the III-nitride-based buffer layer is a partially strained and relaxed buffer layer due to the decomposed III-nitride-based decomposition layer.

In one embodiment, the III-nitride-based buffer layer is an n-type InGaN/GaN SL grown on or above the DSL with a thickness between 100 nm and 1 μm. An average indium (In) composition of the n-type InGaN/GaN SL may be less than 5%. The n-type InGaN/GaN SL may be grown at a temperature higher than 900° C.

Block 806 represents the step of epitaxially growing a III-nitride-based device structure on or above the III-nitride-based buffer, wherein the device structure achieves higher power and higher efficiency in green light emissions as compared to the III-nitride-based device structure without the partially strained and relaxed buffer laver.

In one embodiment, an n-type waveguide layer that is a second n-type InGaN/GaN SL is grown on or above the buffer layer that is the first n-type InGaN/GaN SL. The second n-type InGaN/GaN SL that is the n-type waveguide layer may be grown at a higher indium composition than the n-type InGaN/GaN SL that is the buffer layer with an average composition between In_{0.05}Ga_{0.95}N and In_{0.2}Ga_{0.8}N. An n-type InGaN layer of the second n-type InGaN/GaN SL that is the n-type waveguide layer may be grown at a temperature under 950° C. with a nitrogen carrier gas along with a first portion of the DSL. A second portion of the DSL may be grown at a high temperature above 900° C. with the inclusion of hydrogen in a carrier gas.

An active region comprised of at least an InGaN quantum well (QW), cap layer, and barrier, is grown on or above the n-type waveguide layer. The cap layer may be GaN or AlGaN grown at or near the InGaN QW growth temperature, which is below 900° C.: and the barrier may be GaN or InGaN, wherein the barrier is grown in part or completely at a temperature above the InGaN QW growth temperature.

A p-type AlGaN electron blocking layer (EBL) may be grown on or above the active region at a high temperature above 900° C. with the inclusion of hydrogen in a carrier gas.

A p-type waveguide layer that is a p-type InGaN/GaN SL may be grown on or above the p-type AlGaN EBL or the active region. The p-type InGaN/GaN SL that is the waveguide layer may be grown at a higher indium composition than the n-type InGaN/GaN SL that is the buffer layer, with an average composition between In_{0.05}Ga_{0.95}N and In_{0.2}Ga_{0.8}N. A first portion of a p-type InGaN layer of the p-type InGaN/GaN SL that is the p-type waveguide layer may be grown at a temperature under 950° C. with a nitrogen carrier gas. A second portion of the p-type GaN layer of the p-type InGaN/GaN SL that is the p-type waveguide layer may be grown at a temperature above 900° C. with the inclusion of hydrogen in a carrier gas.

A p-type GaN layer with a thickness greater than 100 nm may be grown on or above the active region, p-type AlGaN EBL and/or p-type waveguide layer. The p-type GaN layer growth temperature may be higher than 920° C.

A p++GaN layer with a thickness less than 30 nm may be grown on or above the p-type GaN layer. An n-GaN, n++GaN, or n-GaN and n++GaN layer may be grown on or above the p++GaN layer.

Block 807 represents the step of processing the III-nitride-based device structure into a III-nitride-based device, such as an LED or LD, and then packaging the device. This may include, but is not limited to, depositing transparent conducting oxide (TCO) layers, sub-mounting, etching mesas or ridge waveguides, passivating sidewalls, depositing electrodes, etc.

Block 808 represents the end result of the method, namely, a III-nitride-based device structure according to the present invention, wherein the device structure achieves higher power and higher efficiency in green light emissions as compared to the III-nitride-based device structure without the partially strained and relaxed buffer layer. The III-nitride-based device may comprise, for example, an LED, LD, or other device.

The above steps may be modified, eliminated, repeated, or completed in any desired order, without departing from the scope of the present invention.

### Alternatives and Variations

A number of alternatives and variations are available for the present invention, as set forth below:
1) A method, comprising creating a III-nitride-based decomposition stop layer (DSL) on or above a III-nitride-based decomposition layer (DL), wherein a temperature is increased to decompose the III-nitride-based decomposition layer; and growing a III-nitride-based device structure on or above the III-nitride-based decomposition stop layer.
2) In 1), a step-flow surface morphology is observed in at least a 5 μm×5 μm area of the top surface of the III-nitride-based device structure by atomic force microscopy measurement.
3) In 1), the DL is InGaN or multiple periods of an InGaN/GaN SL grown at a temperature between 700° C. and 800° C.
4) In 1), the DSL is n-type GaN or n-type InₓGa₁₋ₓN/GaN SL with x<0.05.
5) In 4), the thickness of the n-type GaN is greater than 20 nm.
6) In 4), the thickness of the n-type GaN is less than 3 μm.
7) In 4-6), the n-type GaN is grown at a temperature higher than 1000° C. with the inclusion of hydrogen in the carrier gas.
8) In 7), the first layer of the n-type GaN is grown with a carrier gas consisting essentially of nitrogen.
9) In 4-8), an n-type InGaN/GaN SL buffer layer is grown on or above the n-type GaN with a thickness between 100 nm and 1 μm.
10) In 9), an average indium (In) composition of an n-type InGaN/GaN SL buffer layer is less than 5%.
11) In 9-10), the n-type InGaN/GaN SL buffer layer is grown with a temperature higher than 900° C.
12) In 9-11), a second n-type InGaN/GaN SL waveguiding layer is grown on or above the n-type InGaN/GaN SL buffer layer.
13) In 12), the second n-type InGaN/GaN SL waveguiding layer is grown at a higher composition than the buffer with average composition between In_{0.25}Ga_{0.95}N and In_{0.2}Ga_{0.8}N.
14) In 12-13), the n-type InGaN layer of the second n-type InGaN/GaN SL waveguiding layer is grown under 950° C. with nitrogen carrier gas along with a first portion of the n-type GaN layer.
15) In 14), a second portion of the n-type GaN layer is grown at a high temperature, similar to that of p-type GaN, above 900° C. with the inclusion of hydrogen in the carrier gas.
16) In 12-15), an active region comprised of an InGaN QW, cap layer, and barrier, is grown on or above the second n-type InGaN/GaN SL waveguiding layer.
17) In 16), the cap layer is GaN or AlGaN grown at or near the InGaN QW growth temperature, which is below 900° C.
18) In 16), the barrier is GaN or InGaN.
19) In 16-18), the barrier is grown in part or completely at a temperature above the InGaN QW growth temperature.
20) In 16-19), a p-type AlGaN EBL is grown on or above the active region at a high temperature, similar to that of p-type GaN, above 900° C. with the inclusion of hydrogen in the carrier gas.
21) In 16-20), a p-type InGaN/GaN SL waveguiding layer is grown on or above the AlGaN EBL or the active region.
22) In 21), the p-type InGaN/GaN SL waveguiding layer is grown at a higher indium composition than the buffer with an average composition between In_{0.05}Ga_{0.95}N and In_{0.2}Ga_{0.8}N.
23) In 21-22), the p-type InGaN layer of the p-type InGaN/GaN SL waveguiding layer is grown under 950° C. with a nitrogen carrier gas along with a first portion of the p-type GaN layer.
24) In 21-23), a second portion of the p-type GaN layer is grown at a high temperature, similar to that of p-type GaN, above 900° C. with the inclusion of hydrogen in the carrier gas.
25) In 16-24), a p-type GaN layer with a thickness greater than 100 nm is grown on or above the active region, p-type AlGaN EBL and/or p-type InGaN/GaN SL waveguiding layer.
26) In 25), the p-type GaN layer growth temperature is higher than 920° C.
27) In 25), a p++GaN layer with a thickness less than 30 nm is grown on or above the p-type GaN layer.
28) In 27), n-GaN, n++GaN, or n-GaN and n++GaN, is grown on or above the p++GaN layer.
29) In 1-28), the device structure is an LED or LD.
30) In 1-29), the device structure including the strain relaxed template (SRT) is grown on or above a GaN template grown on a substrate, wherein the substrate is sapphire, silicon (Si), silicon carbide (SiC), glass, III-nitride-based such as GaN and AIN with any crystal orientation such as nonpolar and semipolar, or other materials.

### REFERENCES

The following publications are incorporated by reference herein:
1. S. Masui, Y. Nakatsu, D. Kasahara, S. Nagahama, Proc. Of SPIE OPTO, 10104, 101041H-7 (2017).
2. Y. Nakatsu, Y. Nagao, K. Kozuru, T. Hirao, E. Okahisa, S. Masui, T. Yanamoto, S. Nagahama, Proc. Of SPIE OPTO, 10918, 109181D-1 (2019).
3. M. Murayama, Y. Nakayama, K. Yamazaki, Y. Hoshina, H. Watanabe, N. Fuutagawa, H. Kawanishi, T. Uemura, H. Narui, Phys. Status Solidi A, 215, 1700513 (2018).
4. Y. Kawaguchi, M. Shimizu, K. Hiramatsu, N. Sawaki, Mater. Res. Soc. Symp. Proc. 449, 89-94 (1997).
5. A. Even, G. Laval, O. Ledoux, P. Ferret, D. Sotta, E. Guiot, F. Levy, I. C. Robin, A. Dussaigne, Appl. Phys. Lett., 110, 262103 (2017).
6. S. Pasayat, C. Gupta, D. Acker-James, D. Cohen, S. DenBaars, S. Nakamura, U. Mishra, Semicond. Sci. Technol., 34, 115020 (2019).
7. S. Pasayat, C. Gupta, M. Wong, R. Ley, M. Gordon, S. DenBaars, S. Nakamura, S. Keller, U. Mishra, Appl. Phys. Express, 14, 011004 (2021).
8. S. Pasayet, C. Gupta, M. Wong, Y. Wang, S. Nakamura, S. DenBaars, S. Keller, U. Mishra, Appl. Phys. Lett., 116, 111101 (2020).
9 S. Pasayat, R. Ley, C. Gupta, M. Wong, C. Lynsky, Y. Wang, M. Gordon, S. Nakamura, S. DenBaars, S. Keller, U. Mishra, Appl. Phys. Lett., 117 061105 (2020).
10. A. Dussaigne, P. Le Maitre, H. Haas, J.-C. Pillet, F. Barbier, A. Grenier, N. Michit, A. Jannaud, R. Templier, D. Vaufrey, F. Rol, O. Ledoux, D. Sotta, Appl. Phys. Express, 14, 092011 (2021).
11. A. Dussaigne, F. Barbier, B. Samuel, A. Even, R. Templier, F. Levy, O. Ledoux, M. Rozhavskaia, D. Sotta, J. Cryst. Growth, 533, 125481 (2020).
12. P. Chan, S. DenBaars, S. Nakamura, Appl. Phys. Lett., 119, 131106 (2021).
13. P. Chan, V. Rienzi, N. Lim, H.-M. Chang, M. Gordon, S. DenBaars, S. Nakamura, Appl. Phys. Express, 14, 101002 (2021).

### CONCLUSION

This concludes the description of the preferred embodiment of the present invention. The foregoing description of one or more embodiments of the invention has been presented for the purposes of illustration and description. It is not intended 5 to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
creating a III-nitride-based decomposition layer (DL) on or above a substrate;
creating a III-nitride-based decomposition stop layer (DSL) on or above the III-nitride-based DL, wherein the III-nitride-based DL, but not the III-nitride-based DSL, is decomposed by an increase in temperature;
creating a III-nitride-based buffer layer on or above the III-nitride-based DSL, wherein the III-nitride-based buffer layer is a partially strained and relaxed buffer layer due to the decomposed III-nitride-based DL; and
growing a III-nitride-based device structure on or above the III-nitride-based buffer layer, wherein the device structure achieves higher power and higher efficiency in green light emissions as compared to the III-nitride-based device structure without the partially strained and relaxed buffer layer.

2. The method of claim 1, wherein a step-flow surface morphology is observed in at least a 5 μm×5 μm area of a top surface of the III-nitride-based device structure by atomic force microscopy measurement.

3. The method of claim 1, wherein the III-nitride-based DL is InGaN or multiple periods of an InGaN/GaN superlattice (SL) grown at a temperature between 700° C. and 800° C.

4. The method of claim 1, wherein the III-nitride-based DSL is n-type GaN or an n-type InₓGa₁₋ₓN/GaN SL with x<0.05.

5. The method of claim 4, wherein the III-nitride-based DSL is the n-type GaN with a thickness greater than 20 nm.

6. The method of claim 4, wherein the III-nitride-based DSL is the n-type GaN with a thickness less than 3 μm.

7. The method of claim 4, wherein the III-nitride-based DSL is the n-type GaN grown at a temperature higher than 1000° C. with the inclusion of hydrogen in the carrier gas.

8. The method of claim 7, wherein a first layer of the n-type GaN is grown using a carrier gas consisting essentially of nitrogen.

9. The method of claim 4, wherein the buffer layer is an n-type InGaN/GaN SL grown on or above the n-type GaN with a thickness between 100 nm and 1 μm.

10. The method of claim 9, wherein an average indium (In) composition of the n-type InGaN/GaN SL is less than 5%.

11. The method of claim 9, wherein the n-type InGaN/GaN SL is grown with a temperature higher than 900° C.

12. The method of claim 9, wherein an n-type waveguide layer that is an n-type InGaN/GaN SL is grown on or above the buffer layer.

13. The method of claim 12, wherein the n-type InGaN/GaN SL that is the n-type waveguide layer is grown at a higher indium composition than the n-type InGaN/GaN SL that is the buffer layer, with the higher indium composition between In_{0.05}Ga_{0.95}N and In_{0.2}Ga_{0.8}N.

14. The method of claim 12, wherein an n-type InGaN layer of the n-type InGaN/GaN SL that is the n-type waveguide layer is grown under 950° C. with a nitrogen carrier gas along with a first portion of the n-type GaN layer that is the III-nitride-based DSL.

15. The method of claim 14, wherein a second portion of the n-type GaN layer that is the III-nitride-based DSL is grown at a high temperature above 900° C. with the inclusion of hydrogen in a carrier gas.

16. The method of claim 12, wherein an active region comprised of at least an InGaN quantum well (QW), cap layer, and barrier, is grown on or above the n-type waveguide layer.

17. The method of claim 16, wherein the cap layer is GaN or AlGaN grown at or near the InGaN QW growth temperature, which is below 900° C.

18. The method of claim 16, wherein the barrier is GaN or InGaN.

19. The method of claim 16, wherein the barrier is grown in part or completely at a temperature above the InGaN QW growth temperature.

20. The method of claim 16, wherein a p-type AlGaN electron blocking layer (EBL) is grown on or above the active region at a high temperature above 900° C. with the inclusion of hydrogen in a carrier gas.

21. The method of claim 20, wherein a p-type waveguide layer that is a p-type InGaN/GaN SL is grown on or above the p-type AlGaN EBL or the active region.

22. The method of claim 21, wherein the p-type InGaN/GaN SL that is the p-type waveguide layer is grown at a higher indium composition than the n-type InGaN/GaN SL that is the buffer layer, with the higher indium composition between In_{0.05}Ga_{0.95}N and In_{0.2}Ga_{0.8}N.

23. The method of claim 21, wherein a first portion of a p-type InGaN layer of the p-type InGaN/GaN SL that is the p-type waveguide layer is grown at a temperature under 950° C. with a nitrogen carrier gas.

24. The method of claim 23, wherein a second portion of the p-type GaN layer of the p-type InGaN/GaN SL that is the p-type waveguide layer is grown at a temperature above 900° C. with the inclusion of hydrogen in a carrier gas.

25. The method of claim 24, wherein a p-type GaN layer with a thickness greater than 100 nm is grown on or above the active region, p-type AlGaN EBL and/or p-type waveguide layer.

26. The method of claim 25, wherein the p-type GaN layer growth temperature is higher than 920° C.

27. The method of claim 25, wherein a p++GaN layer with a thickness less than 30 nm is grown on or above the p-type GaN layer.

28. The method of claim 27, wherein n-GaN, n++GaN, or n-GaN and n++GaN, is grown on or above the p++GaN layer.

29. The method of claim 1, wherein the device structure is a light emitting diode (LED) or laser diode (LD).

30. The method of claim 29, wherein the device structure including a strain relaxed template (SRT) comprised of the III-nitride-based DL and the III-nitride-based DSL is grown on or above a GaN template grown on a substrate, and the substrate is sapphire, silicon (Si), silicon carbide (SiC), glass, III-nitride-based such as GaN and AlN with any crystal orientation such as nonpolar and semipolar, or other materials.

31. A device, comprising:
a III-nitride-based decomposition layer (DL) created on or above a substrate;
a III-nitride-based decomposition stop layer (DSL) created on or above the III-nitride-based DL, wherein the III-nitride-based DL, but not the III-nitride-based DSL, is decomposed by an increase in temperature;
a III-nitride-based buffer layer created on or above the III-nitride-based DSL, wherein the III-nitride-based buffer layer is a partially strained and relaxed buffer layer due to the decomposed III-nitride-based DL; and
a III-nitride-based device structure grown on or above the III-nitride-based buffer layer, wherein the device structure achieves higher power and higher efficiency in green light emissions as compared to the III-nitride-based device structure without the partially strained and relaxed buffer layer.
